(19) United States
(12) Patent Application Publication
(10) Pub. No.: US 2026/0293480 A1
(43) Pub. Date: Sep. 24, 2026

(54) DISPLAY APPARATUS, METHOD OF MANUFACTURING DISPLAY APPARATUS, AND ELECTRONIC APPARATUS INCLUDING DISPLAY APPARATUS

(71) Applicant: Samsung Display Co., Ltd., Yongin-si (KR)

(72) Inventors: Jinyoung Yun, Yongin-si (KR); Beomjoon Kim, Yongin-si (KR); Keunchan Oh, Yongin-si (KR); Seokgyu Yoon, Yongin-si (KR); Sanghyun Han, Yongin-si (KR)

(21) Appl. No.: 19/548,543

(22) Filed: Feb. 24, 2026

(30) Foreign Application Priority Data
Mar. 24, 2025 (KR) 10-2025-0037509

(51) Int. Cl. H10K 59/35; H10K 59/00; H10K 59/12

(52) U.S. Cl. CPC H10K 59/35; H10K 59/1201; H10K 59/771

(57) ABSTRACT

A display apparatus includes: a first electrode; a first functional layer over the first electrode and comprising a P dopant; first to third light-emitting units over the first functional layer; and a second electrode over the first to third light-emitting units, wherein the first light-emitting unit includes: a first-1 light-emitting unit layer having a first-1 area in a plan view; a first charge generation layer over the first-1 light-emitting unit layer, in the first-1 light-emitting unit layer in the plan view, and having a first-2 area that is less than the first-1 area; and a first-2 light-emitting unit layer over the first charge generation layer and overlap the first-1 light-emitting unit layer, wherein the first-2 area is greater than or equal to 40% and less than 100% of the first-1 area.

### CROSS-REFERENCE TO RELATED APPLICATION

The present application claims priority to and the benefit of Korean Patent Application No. 10-2025-0037509, filed on Mar. 24, 2025, in the Korean Intellectual Property Office, the entire disclosure of which is incorporated herein by reference.

### BACKGROUND

### 1. Field

Aspects of some embodiments of the present disclosure relate to a display apparatus, a method of manufacturing the display apparatus, and an electronic apparatus including the display apparatus.

### 2. Description of the Related Art

Display apparatuses may display images in response to receiving information about the images. Display apparatuses may be used as display units of small products such as mobile phones or as display units of large products such as televisions.

A display apparatus may include a plurality of pixels that receive an electrical signal to emit light to display images to the outside. Each pixel may include a light-emitting device, which may be, for example, an organic light-emitting diode in the case of an organic light-emitting display apparatus. In general, a display apparatus may include a thin film transistor and an organic light-emitting diode over a substrate.

Moreover, an electronic apparatus may provide a visual interface necessary for a user through a display apparatus.

The above information disclosed in this Background section is only for enhancement of understanding of the background and therefore the information discussed in this Background section does not necessarily constitute prior art.

### SUMMARY

Aspects of some embodiments of the present disclosure relate to a display apparatus, a method of manufacturing the display apparatus, and an electronic apparatus including the display apparatus, and for example, to a display apparatus with improved image quality, a method of manufacturing the display apparatus, and an electronic apparatus including the display apparatus.

One or more embodiments include a display apparatus with improved image quality, a method of manufacturing the display apparatus, and an electronic apparatus including the display apparatus. However, these problems are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a first electrode, a first functional layer arranged over the first electrode and including a P dopant, first to third light-emitting units arranged over the first functional layer, and a second electrode arranged over the first to third light-emitting units. According to some embodiments, the first light-emitting unit may include a first-1 light-emitting unit layer having a first-1 area in a plan view, a first charge generation layer arranged over the first-1 light-emitting unit layer, arranged in the first-1 light-emitting unit layer in a plan view, and having a first-2 area that is less than the first-1 area, and a first-2 light-emitting unit layer arranged over the first charge generation layer and overlap the first-1 light-emitting unit layer, wherein the first-2 area may be greater than or equal to 40% (or about 40%) and less than 100% (or about 100%) of the first-1 area.

According to some embodiments, a magnitude of a leakage current occurring between the first functional layer and the first charge generation layer may be less than 3% (or about 3%) of a magnitude of a vertical current flowing between the first electrode and the second electrode.

According to some embodiments, a number of light-emitting unit layers included in the first light-emitting unit may be greater than a number of light-emitting unit layers included in the second light-emitting unit or a number of light-emitting unit layers included in the third light-emitting unit.

According to some embodiments, the first charge generation layer may include an n-type first-1 charge generation layer arranged over the first-1 light-emitting unit layer, and a p-type first-2 charge generation layer arranged over the first-1 charge generation layer, wherein the first-1 charge generation layer may be spaced apart from the first functional layer by the first-1 light-emitting unit layer.

According to some embodiments, the first-2 light-emitting unit layer may cover an upper surface and an outer surface of the first charge generation layer.

According to some embodiments, in a plan view, an end of the first-2 light-emitting unit layer may cover an upper surface of an end of the first-1 light-emitting unit layer.

According to some embodiments, the end of the first-2 light-emitting unit layer may directly contact the end of the first-1 light-emitting unit layer.

According to some embodiments, in a plan view, the first-2 light-emitting unit layer may have a first-3 area that is greater than the first-2 area.

According to some embodiments, the first-2 area may be 60% (or about 60%) to 90% (or about 90%) of the first-1 area, and a magnitude of a leakage current occurring between the first functional layer and the first charge generation layer may be 2% (or about 2%) or less of a magnitude of a vertical current flowing between the first electrode and the second electrode.

According to some embodiments, the first-2 area may be 60% (or about 60%) to 70% (or about 70%) of the first-1 area, and a magnitude of a leakage current occurring between the first functional layer and the first charge generation layer may be 1% (or about 1%) or less of a magnitude of a vertical current flowing between the first electrode and the second electrode.

According to some embodiments, the first-1 light-emitting unit layer and the first-2 light-emitting unit layer may generate visible light of a first wavelength band.

According to one or more embodiments, a method of manufacturing a display apparatus includes forming a first functional layer over a first electrode, forming a first-1 light-emitting unit layer over the first functional layer by using a first-1 mask having a first-1 opening having a first-1 area, forming a first charge generation layer over the first-1 light-emitting unit layer by using a first-2 mask having a first-2 opening having a first-2 area that is less than the first-1 area, forming a first-2 light-emitting unit layer over the first charge generation layer by using a first-3 mask having a first-3 opening having a first-3 area, and forming a second electrode over the first-2 light-emitting unit layer, wherein the first-2 area is greater than or equal to 40% (or about 40%) and less than 100% (or about 100%) of the first-1 area.

According to some embodiments, a magnitude of a leakage current occurring between the first functional layer and the first charge generation layer may be less than 3% (or about 3%) of a magnitude of a vertical current flowing between the first electrode and the second electrode.

According to some embodiments, the first-3 area may be greater than the first-2 area.

According to some embodiments, the first-2 light-emitting unit layer may cover an upper surface and a side surface of the first charge generation layer.

According to some embodiments, the first-2 area may be greater than or equal to 60% (or about 60%) and less than 90% (or about 90%) of the first-1 area, and a magnitude of a leakage current occurring between the first functional layer and the first charge generation layer may be 2% (or about 2%) or less of a magnitude of a vertical current flowing between the first electrode and the second electrode.

According to some embodiments, the first-2 area may be 60% (or about 60%) to 70% (or about 70%) of the first-1 area, and a magnitude of a leakage current occurring between the first functional layer and the first charge generation layer may be 1% (or about 1%) or less of a magnitude of a vertical current flowing between the first electrode and the second electrode.

According to some embodiments, the first-1 light-emitting unit layer and the first-2 light-emitting unit layer may generate visible light of a first wavelength band.

According to one or more embodiments, an electronic apparatus includes a memory storing data information, a processor configured to generate a data signal and/or a control signal based on the data information, and a display apparatus operating based on the data signal and/or the control signal. According to some embodiments, the display apparatus may include a first electrode, a first functional layer arranged over the first electrode, first to third light-emitting units arranged over the first functional layer, and a second electrode arranged over the first to third light-emitting units. According to some embodiments, the first light-emitting unit may include a first-1 light-emitting unit layer having a first-1 area in a plan view, a first charge generation layer arranged over the first-1 light-emitting unit layer, arranged in the first-1 light-emitting unit layer in a plan view, and having a first-2 area that is less than the first-1 area, and a first-2 light-emitting unit layer arranged over the first charge generation layer and overlap the first-1 light-emitting unit layer, wherein the first-2 area may be greater than or equal to 40% (or about 40%) and less than 100% (or about 100%) of the first-1 area.

According to some embodiments, a magnitude of a leakage current occurring between the first functional layer and the first charge generation layer may be less than 3% (or about 3%) of a magnitude of a vertical current flowing between the first electrode and the second electrode.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a plan view schematically illustrating a display apparatus according to some embodiments;

FIG. 2 is an example of an equivalent circuit diagram schematically illustrating a subpixel of the display apparatus of FIG. 1;

FIG. 3 is an example of a cross-sectional view schematically illustrating a cross-section taken in a display area of FIG. 1;

FIGS. 4 to 13 are cross-sectional views schematically illustrating cross-sections of the display apparatus of FIG. 1 according to a manufacturing sequence of the display apparatus;

FIG. 14 is a cross-sectional view schematically illustrating an example of the cross-section of the display apparatus of FIG. 1;

FIG. 15 is a cross-sectional view schematically illustrating an example of the cross-section of the display apparatus of FIG. 1;

FIG. 16 is a cross-sectional view schematically illustrating an example of the cross-section of the display apparatus of FIG. 1;

FIGS. 17 to 19 are cross-sectional views focusing on structural features between a first-1 light-emitting unit layer, a first-2 light-emitting unit layer, and a first functional layer of the display apparatus of FIG. 1;

FIG. 20 is a block diagram of an electronic apparatus according to some embodiments; and

FIG. 21 schematically illustrates electronic apparatuses according to some embodiments.

### DETAILED DESCRIPTION

Reference will now be made in more detail to aspects of some embodiments, examples of which are illustrated in the accompanying drawings, wherein like reference numerals refer to like elements throughout. In this regard, embodiments according to the present disclosure may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and particular embodiments thereof are illustrated in the drawings and will be described herein in detail. The effects and features of the disclosure and methods of achieving them will become more apparent with reference to the embodiments described below in more detail together with the drawings. However, the disclosure is not limited to the embodiments described below and may be implemented in various forms.

Hereinafter, embodiments will be described in detail with reference to the accompanying drawings, and in the following description, like reference numerals will denote like elements and some redundant descriptions thereof may be omitted for conciseness.

It will be understood that although terms such as “first” and “second” may be used herein to describe various elements, these elements should not be limited by these terms and these terms are only used to distinguish one element from another element. Also, as used herein, the singular forms “a,” “an,” and “the” are intended to include the plural forms as well, unless the context clearly indicates otherwise.

It will be understood that when an element such as a layer, a region, or a plate is referred to as being “on” another element, it may be “directly on” the element or may be “indirectly on” the other element with one or more intervening elements therebetween.

Also, sizes of components in the drawings may be exaggerated for convenience of description. In other words, because the sizes and shapes of elements in the drawings are arbitrarily illustrated for convenience of description, the disclosure is not limited thereto.

It will be understood that terms such as “comprise,” “include,” and “have” used herein specify the presence of stated features or elements, but do not preclude the presence or addition of one or more other features or elements.

It will be understood that when a layer, region, or element is referred to as being “on” another layer, region, or element, it may be “directly on” the other layer, region, or element or may be “indirectly on” the other layer, region, or element with one or more intervening layers, regions, or elements therebetween.

When a certain embodiment may be implemented differently, a particular process order may be performed differently from the described order. For example, two consecutively described processes may be performed substantially at the same time or performed in an order opposite to the described order.

As used herein, “A and/or B” represents the case of A, B, or A and B. Also, “at least one of A and B” represents the case of A, B, or A and B.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component or may be “indirectly electrically connected to” the other layer, region, or component with one or more intervening layers, regions, or components therebetween.

Also, herein, the X axis, the Y axis, and the Z axis are not limited to three axes of the rectangular coordinate system and may be interpreted in a broader sense. For example, the X axis, the Y axis, and the X axis may be perpendicular to one another or may represent different directions that are not perpendicular to one another.

Hereinafter, based on the above, a display apparatus and a method of manufacturing the display apparatus according to some embodiments will be described in more detail.

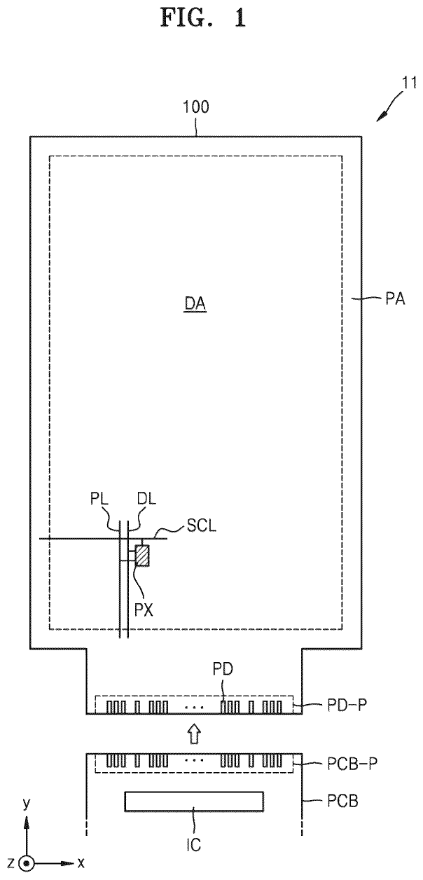

FIG. 1 is a plan view schematically illustrating a display apparatus according to some embodiments.

As illustrated in FIG. 1, a display apparatus 11 may include a display area DA and a peripheral area PA located outside (e.g., in a periphery or outside a footprint of) the display area DA. In FIG. 1, the display area DA is illustrated as having a rectangular shape; however, embodiments according to the present disclosure are not limited thereto. For example, the display area DA may have any of various shapes such as a circular shape, elliptical shape, polygonal shape, an irregular shape, or particular figure shape.

The display area DA may be an area for displaying images, and a plurality of subpixels PX may be arranged in the display area DA. Each of the plurality of subpixels PX may include a display device such as an organic light-emitting device. Each of the plurality of subpixels PX may emit, for example, red, green, or blue light. The subpixel PX may be connected to a pixel circuit including a thin film transistor and a storage capacitor. The pixel circuit may be connected to a scan line SCL configured to transmit a scan signal, a data line DL intersecting the scan line SCL and configured to transmit a data signal, and a driving voltage line PL configured to supply a driving voltage. For example, the data line DL and the driving voltage line PL may extend in a y-axis direction (hereinafter referred to as a first direction), and the scan line SCL may extend in an x-axis direction (hereinafter referred to as a second direction).

The subpixel PX may emit light with a brightness corresponding to an electrical signal received from the data line DL. The display area DA may display certain images through the light emitted from the subpixel PX. For reference, the subpixel P may be defined as an emission area emitting any one of red light, green light, and blue light.

The peripheral area PA may be an area in which a subpixel PX is not arranged and may be an area that does not display images. A power supply line for driving the subpixel PX may be located in the peripheral area PA. Also, pads PD may be arranged in the peripheral area PA, and the peripheral area PA may include a pad area PD-P in which the pads PD are arranged.

The subpixels PX described above may constitute a pixel. A pixel may include three types of subpixels PX corresponding to three wavelength bands of visible light. A pixel may be collectively referred to as a light-emitting device.

An integrated circuit device IC such as a driver IC may be mounted on a printed circuit board PCB including a driving circuit unit, and terminals electrically connected to the integrated circuit device IC may be arranged in a terminal area PCB-P of the printed circuit board PCB. The terminal area PCB-P may correspond to the pad area PD-P, and the pads PD described above may be electrically connected to the terminals of the terminal area PCB-P in the peripheral area PA.

For reference, because the display apparatus 11 includes a substrate 100, the substrate 100 may be understood as including the display area DA and the peripheral area PA. The substrate 100 will be described below in more detail.

Also, a plurality of transistors may be arranged in the display area DA. Regarding the plurality of transistors, depending on the type (N type or P type) and/or the operation condition of the transistor, a first terminal of the transistor may be a source electrode or a drain electrode, and a second terminal of the transistor may be an electrode that is different from the first terminal among the source electrode and the drain electrode. For example, when the first terminal is a source electrode, the second terminal may be a drain electrode.

Hereinafter, an organic light-emitting display apparatus will be described as an example of a display apparatus according to some embodiments; however, the display apparatus of the disclosure is not limited thereto. According to some embodiments, the display apparatus of the disclosure may be an inorganic light-emitting display apparatus or may be a display apparatus such as a quantum dot light-emitting display apparatus. For example, an emission layer included in the display apparatus may include an organic material or an inorganic material. In some cases, the display apparatus may include an emission layer and quantum dots located on the path of light emitted from the emission layer.

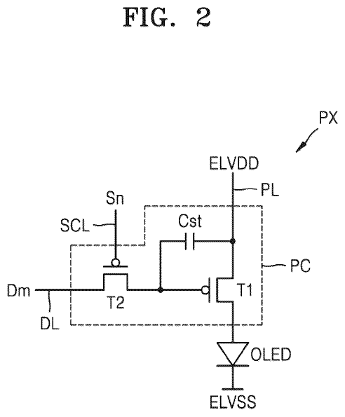

FIG. 2 is an example of an equivalent circuit diagram schematically illustrating a subpixel of the display apparatus 11 of FIG. 1. The equivalent circuit diagram of FIG. 2 may be a basic equivalent circuit diagram, and at least one of the equivalent circuit diagrams variously modified by applying the equivalent circuit diagram of FIG. 2 may be applied to a display apparatus according to some embodiments.

For convenience of description, a pMOS-type thin film transistor is illustrated in FIG. 2; however, the pixel circuit stated herein is not limited thereto and may be variously modified.

As illustrated in FIG. 2, each subpixel PX may include a pixel circuit PC connected to a scan line SCL and a data line DL and a light-emitting device OLED connected to the pixel circuit PC.

For example, the pixel circuit PC may include a driving thin film transistor T1, a switching thin film transistor T2, and a storage capacitor Cst. The switching thin film transistor T2 may be electrically connected to the scan line SCL and the data line DL and may be configured to transmit a data signal Dm input through the data line DL to the driving thin film transistor T1 according to a scan signal Sn input through the scan line SCL.

For example, the driving thin film transistor T1 may be a thin film transistor for a driving operation, and the switching thin film transistor T2 may be a thin film transistor for a switching operation.

For example, the storage capacitor Cst may be connected to the switching thin film transistor T2 and a driving voltage line PL and may be configured to store a voltage corresponding to the difference between a voltage received from the switching thin film transistor T2 and a first power voltage ELVDD (or a driving voltage) supplied to the driving voltage line PL.

For example, the driving thin film transistor T1 may be connected to the driving voltage line PL and the storage capacitor Cst and may be configured to control a driving current flowing from the driving voltage line PL through the light-emitting device OLED in response to a voltage value stored in the storage capacitor Cst. The light-emitting device OLED may emit light with a certain brightness according to the driving current.

The light-emitting device OLED may receive a second power voltage ELVSS (or a common voltage). For example, the light-emitting device OLED may receive the second power voltage ELVSS (or the common voltage) through an opposite electrode (cathode), and the light-emitting device OLED may emit light with a certain brightness by the driving current according to the voltage difference between the first power voltage ELVDD (or the driving voltage) and the second power voltage ELVSS (or the common voltage).

FIG. 2 illustrates a case where the pixel circuit PC includes two thin film transistors and one storage capacitor Cst; however, embodiments according to the present disclosure are not limited thereto. For example, the pixel circuit PC may include two or more capacitors and may also include three or more thin film transistors.

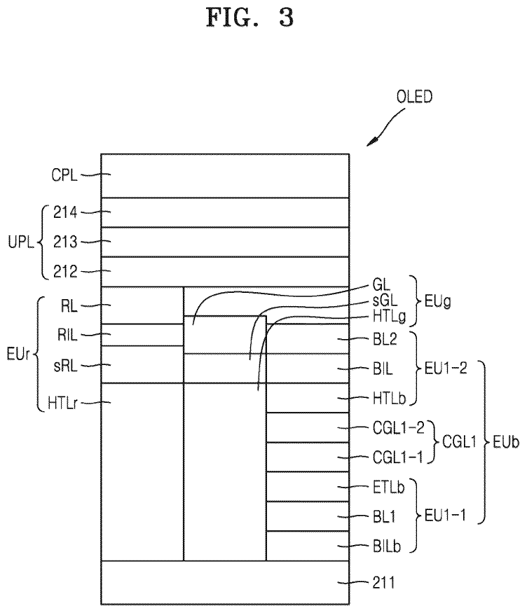

FIG. 3 is a conceptual diagram schematically illustrating a structure of the light-emitting device mentioned in the description of FIG. 1.

The light-emitting device OLED of FIG. 3 may schematically illustrate at least three subpixels included in one pixel. For example, the light-emitting device OLED of FIG. 3 may include subpixels capable of representing three colors (e.g., RGB).

The light-emitting device OLED may include light-emitting units arranged over pixel electrodes described below. The pixel electrodes described below may be referred to as first electrodes.

The light-emitting device OLED may include a first functional layer 211 arranged over the pixel electrodes described below. For example, the first functional layer 211 may be a hole injection layer. The first functional layer 211 may be a P-doped layer including a P dopant.

The light-emitting device OLED may include first to third light-emitting units EUb, EUg, and EUr arranged over the first functional layer 211. Each of the first to third light-emitting units EUb, EUg, and EUr may be a component for emitting visible light of a particular wavelength band and may include a plurality of layers.

For example, the first light-emitting unit EUb may include a first-1 light-emitting unit layer EU1-1 having a first-1 area in a plan view. The first-1 area may refer to a two-dimensional area of the first-1 light-emitting unit layer EU1-1 in the plan view. For example, the first-1 light-emitting unit layer EU1-1 may generate visible light of a first wavelength band (e.g., a blue visible light range).

Herein, the two-dimensional area of the first-1 light-emitting unit layer EU1-1 being the first-1 area may mean that the area of a first-1 opening, which is a pattern of a first-1 mask used to form the first-1 light-emitting unit layer EU1-1, is the first-1 area.

The first-1 light-emitting unit layer EU1-1 may include a first-1 additional functional layer BILb. The first-1 additional functional layer BILb may be arranged over the first functional layer 211 and may directly contact the first functional layer 211. For example, the first-1 additional functional layer BILb may be a layer for adjusting the mobility of holes.

The first-1 light-emitting unit layer EU1-1 may include a first-1 emission layer BL1. The first-1 emission layer BL1 may be arranged over the first-1 additional functional layer BILb and may directly contact the first-1 additional functional layer BILb.

The first-1 light-emitting unit layer EU1-1 may include a first electron transport layer ETLb. The first electron transport layer ETLb may be arranged over the first-1 light-emitting unit layer EU1-1 and may directly contact the first-1 light-emitting unit layer EU1-1.

The first light-emitting unit EUb may include a first charge generation layer CGL1. The first charge generation layer CGL1 may be arranged over the first-1 light-emitting unit layer EU1-1 and may be arranged under a first-2 light-emitting unit layer EU1-2. The first charge generation layer CGL1 may include an N-type first-1 charge generation layer CGL1-1 and a P-type first-2 charge generation layer CGL1-2. The first-1 charge generation layer CGL1-1 may be arranged over the first electron transport layer ETLb and may directly contact the first electron transport layer ETLb. The first-2 charge generation layer CGL1-2 may be arranged over the first-1 charge generation layer CGL1-1 and may directly contact the first-1 charge generation layer CGL1-1.

The first light-emitting unit EUb may include a first charge generation layer CGL1 having a first-2 area in the plan view. The first-2 area may refer to a two-dimensional area of the first charge generation layer CGL1 in the plan view.

The first light-emitting unit EUb may include a first-2 light-emitting unit layer EU1-2 having a first-3 area in the plan view. The first-3 area may refer to a two-dimensional area of the first-2 light-emitting unit layer EU1-2 in the plan view. For example, the first-2 light-emitting unit layer EU1-2 may generate visible light of a first wavelength band (e.g., a blue visible light range). For example, the first-2 light-emitting unit layer EU1-2 may be arranged over the first charge generation layer CGL1 and may directly contact the first charge generation layer CGL1.

The first-2 light-emitting unit layer EU1-2 may include a first-2 hole transport layer HTLb. The first-2 hole transport layer HTLb may be arranged over the first charge generation layer CGL1 and may directly contact the first charge generation layer CGL1.

The first-2 light-emitting unit layer EU1-2 may include a first-2 additional functional layer BIL. The first-2 additional functional layer BIL may be arranged over the first-2 hole transport layer HTLb and may directly contact the first-2 hole transport layer HTLb. For example, the first-2 additional functional layer BIL may be a layer for adjusting the mobility of holes.

The first-2 light-emitting unit layer EU1-2 may include a first-2 emission layer BL2. The first-2 emission layer BL2 may be arranged over the first-2 additional functional layer BIL and may directly contact the first-2 additional functional layer BIL.

For example, the second light-emitting unit EUg may include a second hole transport layer HTLg arranged over the first functional layer 211. The second hole transport layer HTLg may directly contact the first functional layer 211.

The second light-emitting unit EUg may include a second light-emitting auxiliary layer sGL. The second light-emitting auxiliary layer sGL may be arranged over the second hole transport layer HTLg and may directly contact the second hole transport layer HTLg.

The second light-emitting unit EUg may include a second emission layer GL having a second area in the plan view. The second area may refer to a two-dimensional area of the second emission layer GL in the plan view. For example, the second emission layer GL may generate visible light of a second wavelength band (e.g., a green visible light range). For example, the second emission layer GL may be arranged over the second light-emitting auxiliary layer sGL and may directly contact the second light-emitting auxiliary layer sGL.

For example, according to some embodiments, a second additional functional layer may be arranged between the second light-emitting auxiliary layer sGL and the second emission layer GL. For example, the second additional functional layer may be a layer for adjusting the mobility of holes.

For example, the third light-emitting unit EUr may include a third hole transport layer HTLr arranged over the first functional layer 211. The third hole transport layer HTLr may directly contact the first functional layer 211.

The third light-emitting unit EUr may include a third light-emitting auxiliary layer sRL. The third light-emitting auxiliary layer sRL may be arranged over the third hole transport layer HTLr and may directly contact the third hole transport layer HTLr.

The third light-emitting unit EUr may include a third additional functional layer RIL. The third additional functional layer RIL may be arranged over the third light-emitting auxiliary layer sRL and may directly contact the third light-emitting auxiliary layer sRL. For example, the third additional functional layer RIL may be a layer for adjusting the mobility of holes.

The third light-emitting unit EUr may include a third emission layer RL having a third area in the plan view. The third area may refer to a two-dimensional area of the third emission layer RL in the plan view. For example, the third emission layer RL may be a component for emitting light of a third wavelength band (e.g., a red visible light range). For example, the third emission layer RL may be arranged over the third additional functional layer RIL and may directly contact the third light-emitting auxiliary layer sRL.

The light-emitting device OLED may further include an upper functional layer UPL arranged over the first to third light-emitting units EUb, EUg, and EUr. For example, the upper functional layer UPL may include an upper buffer layer 212, an upper electron transport layer 213, and an opposite electrode 214. For example, the upper buffer layer 212 may be a layer for adjusting the mobility of electrons.

For example, the opposite electrode 214 may be referred to as a second electrode. For example, according to some embodiments, an upper electron injection layer may be arranged between the opposite electrode 214 and the upper electron transport layer 213.

The light-emitting device OLED may further include a capping layer CPL arranged over the upper functional layer UPL. For example, the capping layer CPL may improve the light emission efficiency according to the principle of constructive interference. The capping layer CPL may be an organic capping layer including an organic material, an inorganic capping layer including an inorganic material, or a composite capping layer including an organic material and an inorganic material. For example, the capping layer CPL may include lithium fluoride (LiF). The capping layer CPL may be integrally provided as one body over the first to third light-emitting units EUb, EUg, and EUr.

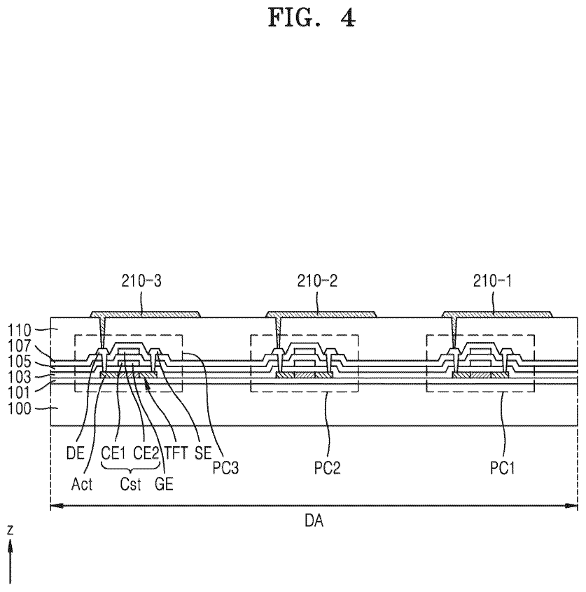

FIGS. 4 to 13 are cross-sectional views schematically illustrating cross-sections of the display apparatus 11 of FIG. 1 according to a manufacturing sequence of the display apparatus.

For reference, redundant descriptions of FIGS. 4 to 13 with the above descriptions may be omitted for conciseness.

As illustrated in FIG. 4, the substrate 100 may include areas corresponding to the display area DA and the peripheral area PA outside the display area DA as described above. The substrate 100 may include various materials having flexible or bendable characteristics.

For example, the substrate 100 may include glass, metal, or polymer resin. Also, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

For example, the substrate 100 may include a multilayer structure including two layers including the polymer resin and a barrier layer arranged between the two layers and including an inorganic material (e.g., silicon oxide, silicon nitride, or silicon oxynitride). Alternatively, the substrate 100 may include an inorganic material such as silicon oxide, silicon nitride, or silicon oxynitride, and various layers and components for screen display (e.g., organic light-emitting display elements and liquid crystal display elements) may be arranged over the substrate 100 including the inorganic material.

A buffer layer 101 may be arranged over the substrate 100. The buffer layer 101 may function as a barrier layer and/or a blocking layer for preventing or reducing contaminants or impurity ions being diffused, preventing or reducing penetration of moisture, contaminants, or external air, and planarizing the surface thereof. The buffer layer 101 may include silicon oxide, silicon nitride, or silicon oxynitride. Also, the buffer layer 101 may adjust a heat supply rate during a crystallization process for forming a semiconductor layer, such that the semiconductor layer may be uniformly crystallized.

A first pixel circuit PC1, a second pixel circuit PC2, and a third pixel circuit PC3 may be arranged over the buffer layer 101. Each of the first to third pixel circuits PC1, PC2, and PC3 may include a transistor TFT and a capacitor Cst. The transistor TFT may include an active layer Act, a gate electrode GE, a source electrode SE, and a drain electrode DE.

The active layer Act may be arranged over the buffer layer 101. According to some embodiments, the active layer Act may include a silicon-based semiconductor material such as amorphous silicon or polycrystalline silicon. According to some embodiments, the active layer Act may include an oxide-based semiconductor material, for example, an oxide of at least one of indium (In), gallium (Ga), stannum (Sn), zirconium (Zr), vanadium (V), hafnium (Hf), cadmium (Cd), germanium (Ge), chromium (Cr), titanium (Ti), aluminum (AI), cesium (Cs), cerium (Ce), or zinc (Zn).

A gate insulating layer 103 may be arranged over the active layer Act, and the gate electrode GE may be arranged over the gate insulating layer 103 so as to overlap the active layer Act in a plane view. The gate electrode GE may include a conductive material such as molybdenum (Mo), aluminum (AI), copper (Cu), titanium (Ti), indium tin oxide (ITO), or indium zinc oxide (IZO) and may include a single layer or multiple layers including the above material.

A first interlayer insulating layer 105 may be arranged over the gate electrode GE, and a second capacitor electrode CE2 may be arranged over the first interlayer insulating layer 105. At least a portion of the gate electrode GE may overlap the second capacitor electrode CE2 in the plan view to function as a first capacitor electrode CE1 of the capacitor Cst. In other words, the gate electrode GE and the first capacitor electrode CE1 may be integrally provided as one body. The second capacitor electrode CE2 may include a conductive material such as molybdenum (Mo), aluminum (Al), copper (Cu), titanium (Ti), indium tin oxide (ITO), or indium zinc oxide (IZO) and may include a single layer or multiple layers including the above material.

A second interlayer insulating layer 107 may be arranged over the second capacitor electrode CE2, and the source electrode SE and the drain electrode DE may be arranged over the second interlayer insulating layer 107. The source electrode SE and the drain electrode DE may include a conductive material such as molybdenum (Mo), aluminum (AI), copper (Cu), titanium (Ti), indium tin oxide (ITO), or indium zinc oxide (IZO) and may include a single layer or multiple layers including the above material. For example, the source electrode SE and the drain electrode DE may have a multilayer structure of Ti/Al/Ti.

Each of the gate insulating layer 103, the first interlayer insulating layer 105, and the second interlayer insulating layer 107 may include an inorganic material such as silicon oxide, silicon nitride, and/or silicon oxynitride and may include a single layer or multiple layers including the above material.

A via insulating layer 110 may be arranged over the first to third pixel circuits PC1, PC2, and PC3. The via insulating layer 110 may include an organic insulating material. For example, the via insulating layer 110 may include benzocyclobutene (BCB), polyimide, hexamethyldisiloxane (HMDSO), polymethylmethacrylate (PMMA), polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any mixture thereof.

A first pixel electrode 210-1, a second pixel electrode 210-2, and a third pixel electrode 210-3 may be arranged apart from each other over the via insulating layer 110. The first pixel electrode 210-1 may be electrically connected to the first pixel circuit PC1, the second pixel electrode 210-2 may be electrically connected to the second pixel circuit PC2, and the third pixel electrode 210-3 may be electrically connected to the third pixel circuit PC3.

As illustrated in FIG. 4, a method of manufacturing a display apparatus according to some embodiments may include an operation of forming a pixel circuit (e.g., first to third pixel circuits) over a substrate, and an operation of forming a pixel electrode (e.g., first to third pixel electrodes) over the pixel circuit.

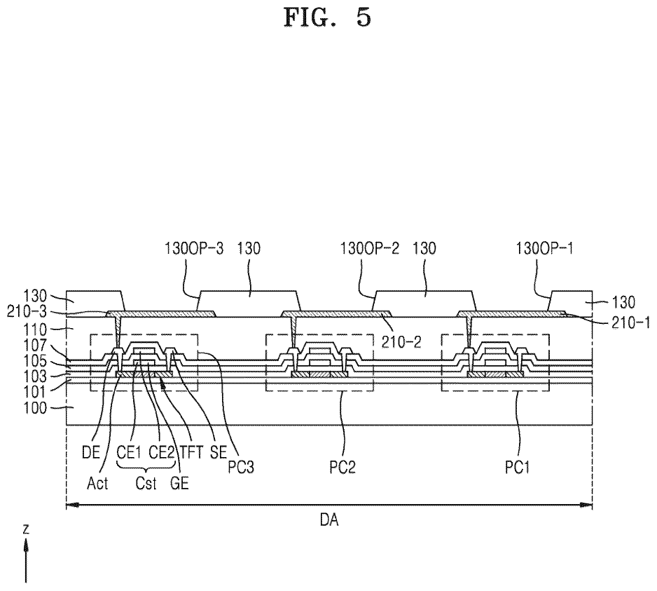

As illustrated in FIG. 5, a pixel definition layer 130 may be arranged over the first pixel electrode 210-1, the second pixel electrode 210-2, and the third pixel electrode 210-3. The pixel definition layer 130 may cover the edge of the first pixel electrode 210-1, the edge of the second pixel electrode 210-2, and the edge of the third pixel electrode 210-3. The pixel definition layer 130 may include a first pixel opening 130OP-1 exposing the center portion of the first pixel electrode 210-1, a second pixel opening 130OP-2 exposing the center portion of the second pixel electrode 210-2, and a third pixel opening 130OP-3 exposing the center portion of the third pixel electrode 210-3.

The pixel definition layer 130 may include an organic insulating material. Alternatively, the pixel definition layer 130 may include an inorganic insulating material such as silicon nitride, silicon oxynitride, or silicon oxide. Alternatively, the pixel definition layer 130 may include an organic insulating material and an inorganic insulating material.

As illustrated in FIG. 5, the method of manufacturing a display apparatus according to some embodiments may include an operation of forming a pixel definition layer that exposes at least a center portion of the pixel electrode upward and covers an edge of the pixel electrode.

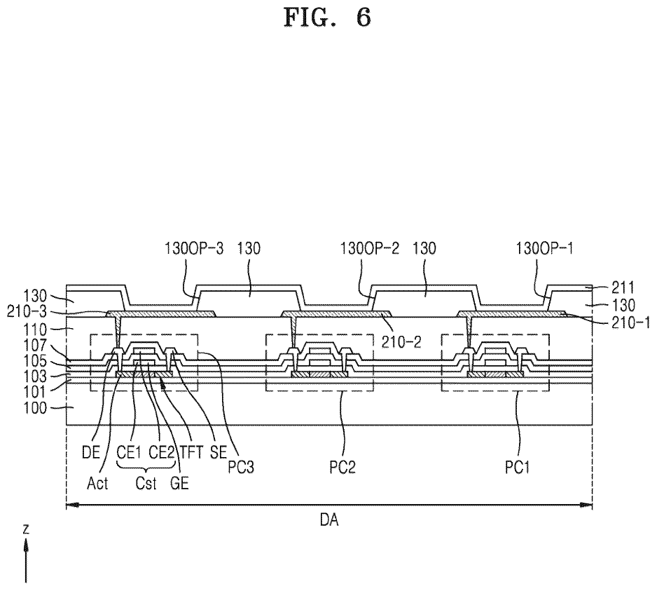

As illustrated in FIG. 6, a first functional layer 211 may be arranged over the first to third pixel electrodes 210-1 to 210-3 and the pixel definition layer 130. The first functional layer 211 may be arranged over the first to third pixel electrodes 210-1 to 210-3 and may be integrally formed as one body. The first functional layer 211 may cover all of the first to third pixel electrodes 210-1 to 210-3. For example, the first functional layer 211 may be a P-doped layer including a P dopant. For example, the first functional layer 211 may be a hole injection layer including a P dopant.

As illustrated in FIG. 6, the method of manufacturing a display apparatus according to some embodiments may include an operation of forming the first functional layer 211 over the pixel electrode (hereinafter also referred to as the first electrode).

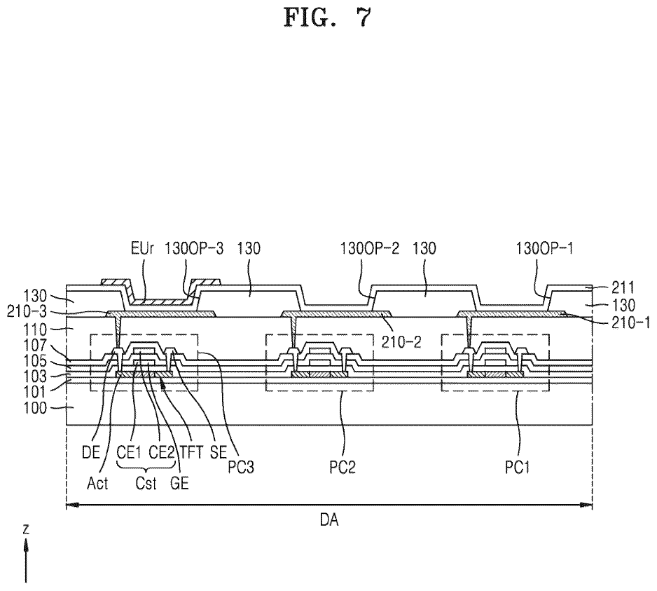

As illustrated in FIGS. 7 to 9, the first-1 light-emitting unit layer EU1-1 to the third light-emitting unit EUr may be arranged over the first functional layer 211.

The first-1 light-emitting unit layer EU1-1 may be arranged over the first pixel electrode, and the first functional layer 211 may be arranged between the first-1 light-emitting unit layer EU1-1 and the first pixel electrode. The first-1 light-emitting unit layer EU1-1 may not overlap other light-emitting units.

The second light-emitting unit EUg may be arranged over the second pixel electrode, and the first functional layer 211 may be arranged between the second light-emitting unit EUg and the second pixel electrode. The second light-emitting unit EUg may not overlap other light-emitting units.

The third light-emitting unit EUr may be arranged over the third pixel electrode, and the first functional layer 211 may be arranged between the third light-emitting unit EUr and the third pixel electrode. The third light-emitting unit EUr may not overlap other light-emitting units.

As illustrated in FIG. 7, the method of manufacturing a display apparatus according to some embodiments may include an operation of forming the third light-emitting unit EUr over the first functional layer 211 by using a third mask having a third opening having a third area.

The third mask may refer to a patterned mask used to form the third light-emitting unit EUr. The pattern formed in the third mask may include a third opening having a third area.

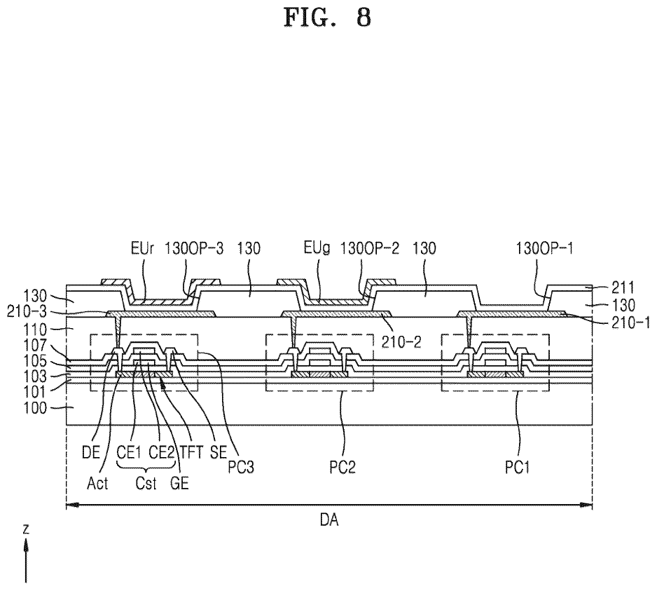

As illustrated in FIG. 8, the method of manufacturing a display apparatus according to some embodiments may include an operation of forming the second light-emitting unit EUg over the first functional layer 211 by using a second mask having a second opening having a second area.

The second mask may refer to a patterned mask used to form the second light-emitting unit EUg. The pattern formed in the second mask may include a second opening having a second area.

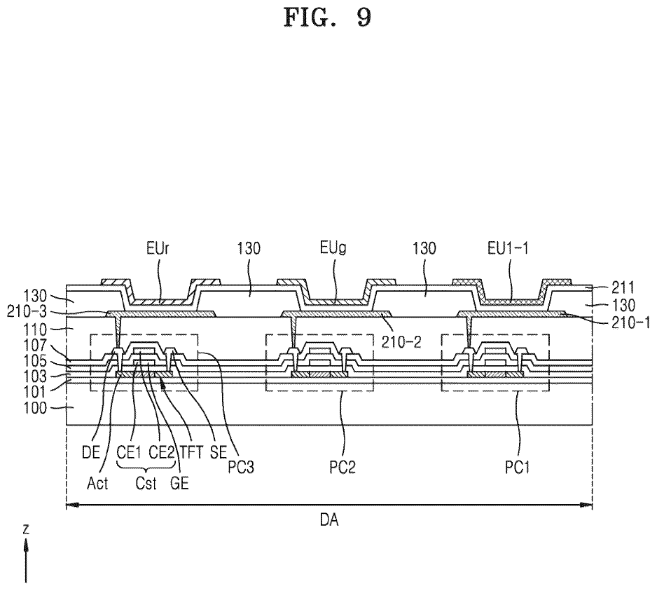

As illustrated in FIG. 9, the method of manufacturing a display apparatus according to some embodiments may include an operation of forming the first-1 light-emitting unit layer EU1-1 over the first functional layer 211 by using a first-1 mask having a first-1 opening having a first-1 area.

The first-1 mask may refer to a patterned mask used to form the first-1 light-emitting unit layer EU1-1. The pattern formed in the first-1 mask may include a first-1 opening having a first-1 area.

For convenience of description, an example of sequentially forming the third light-emitting unit EUr to the first-1 light-emitting unit layer EU1-1 is illustrated in FIGS. 7 to 9; however, this is merely an example and the order of forming the light-emitting unit is not limited thereto.

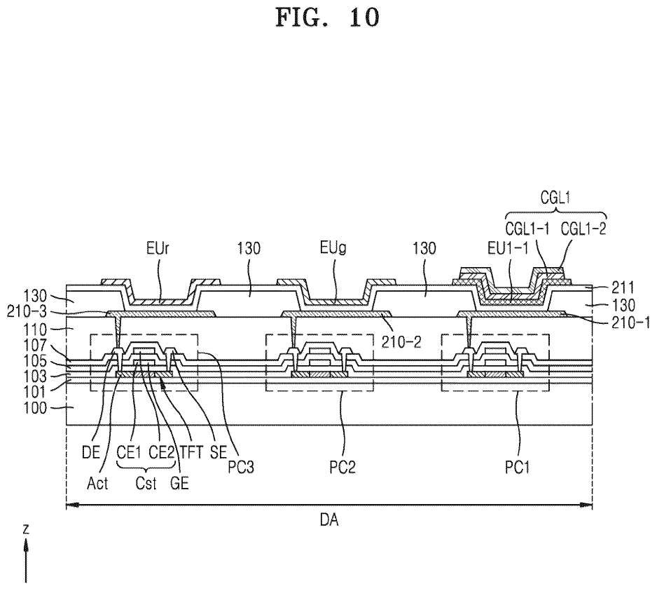

As illustrated in FIG. 10, a first charge generation layer CGL1 may be arranged over the first-1 light-emitting unit layer EU1-1. The first charge generation layer CGL1 may include an n-type first-1 charge generation layer CGL1-1 and a p-type first-2 charge generation layer CGL1-2, the first-1 charge generation layer CGL1-1 may be arranged over the first-1 light-emitting unit layer EU1-1, and the first-2 charge generation layer CGL1-2 may be arranged over the first-1 charge generation layer CGL1-1.

For example, the first-1 charge generation layer CGL1-1 may be spaced apart from the first functional layer 211 by the first-1 light-emitting unit layer EU1-1.

In the plan view, the first charge generation layer CGL1 may be arranged in the first-1 light-emitting unit layer EU1-1. In the plan view, the edge of the first charge generation layer CGL1 may be arranged on an inner side than the edge of the first-1 light-emitting unit layer EU1-1.

The edge of the first-1 charge generation layer CGL1-1 and the edge of the first-2 charge generation layer CGL1-2 may overlap each other in the plan view. The side surface of the first-1 charge generation layer CGL1-1 and the side surface of the first-2 charge generation layer CGL1-2 may form a continuous surface.

The first-1 charge generation layer CGL1-1 may cover at least a portion of the upper surface of the first-1 light-emitting unit layer EU1-1. For example, the first-1 charge generation layer CGL1-1 may not cover an edge of the upper surface of the first-1 light-emitting unit layer EU1-1.

The first-2 charge generation layer CGL1-2 may cover the upper surface of the first-1 charge generation layer CGL1-1. For example, the first-2 charge generation layer CGL1-2 may not cover the outer surface of the first-1 charge generation layer CGL1-1.

As illustrated in FIG. 10, the method of manufacturing a display apparatus according to some embodiments may include an operation of forming the first charge generation layer CGL1 over the first-1 light-emitting unit layer EU1-1 by using a first-2 mask having a first-2 opening having a first-2 area that is less than the first-1 area.

The first-2 mask may refer to a patterned mask used to form the first charge generation layer CGL1. The pattern formed in the first-2 mask may include a first-2 opening having a first-2 area.

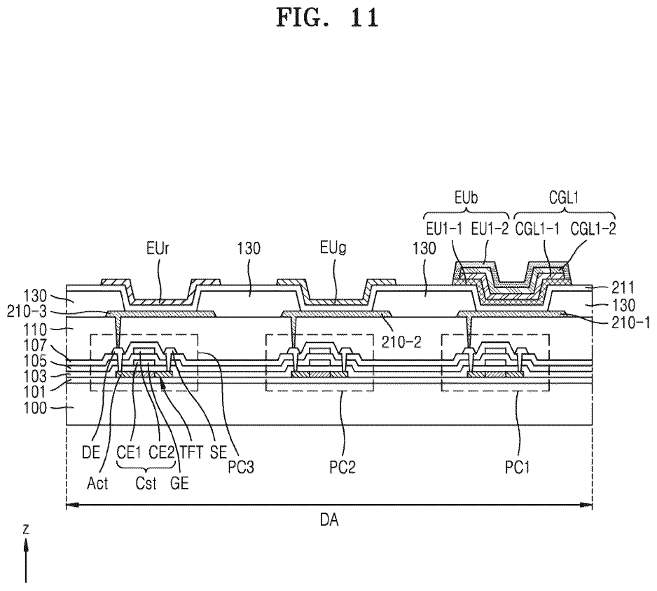

As illustrated in FIG. 11, a first-2 light-emitting unit layer EU1-2 may be arranged over the first charge generation layer CGL1. The first-2 light-emitting unit layer EU1-2 may cover the upper surface of the first charge generation layer CGL1. The first-2 light-emitting unit layer EU1-2 may cover the outer surface of the first charge generation layer CGL1. The edge of the first-2 light-emitting unit layer EU1-2 may extend to the edge of the first-1 light-emitting unit layer EU1-1. For example, the first-2 light-emitting unit layer EU1-2 and the first-1 light-emitting unit layer EU1-1 may directly contact each other.

As illustrated in FIG. 11, the method of manufacturing a display apparatus according to some embodiments may include an operation of forming the first-2 light-emitting unit layer EU1-2 over the first charge generation layer CGL1 by using a first-3 mask having a first-3 opening having a first-3 area.

The first-3 mask may refer to a patterned mask used to form the first-2 light-emitting unit layer EU1-2. The pattern formed in the first-3 mask may include a first-3 opening having a first-3 area.

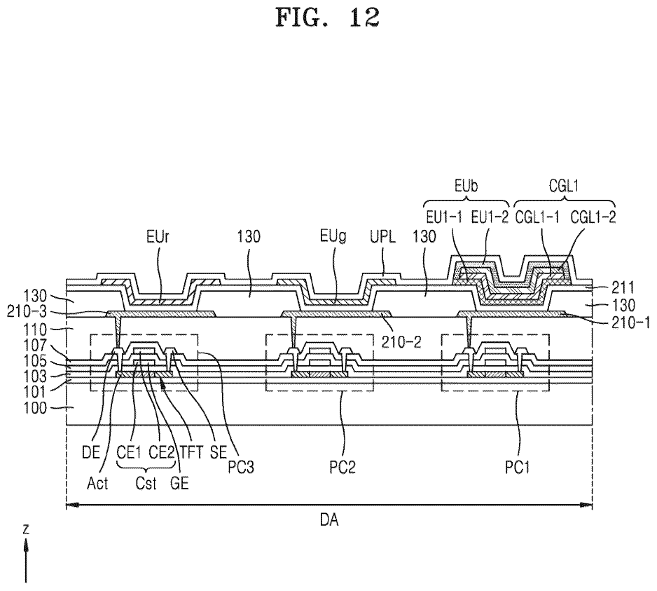

As illustrated in FIG. 12, an upper functional layer UPL may be arranged over the first light-emitting unit EUb, the second light-emitting unit EUg, and the third light-emitting unit EUr. The upper functional layer UPL may cover the upper surface and the outer surface of each of the first light-emitting unit EUb, the second light-emitting unit EUg, and the third light-emitting unit EUr. The upper functional layer UPL may also cover the upper surface of the pixel definition layer exposed upward between the light-emitting units.

As illustrated in FIG. 12, the method of manufacturing a display apparatus according to some embodiments may include an operation of forming the upper functional layer UPL over the first-2 light-emitting unit layer EU1-2.

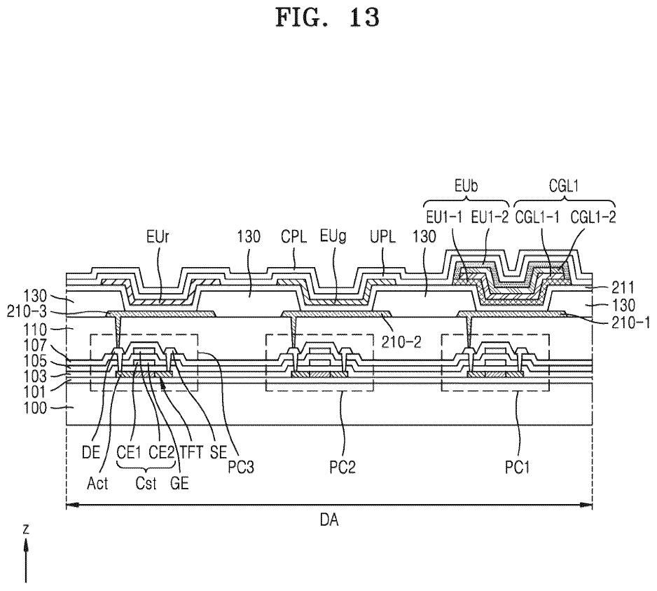

As illustrated in FIG. 13, a capping layer CPL may be arranged over the upper functional layer UPL. The capping layer CPL may cover the upper surface of the upper functional layer UPL. The method of manufacturing a display apparatus according to some embodiments may include an operation of forming the capping layer CPL over the upper functional layer UPL.

As illustrated in FIGS. 10 to 13, the first-1 light-emitting unit layer EU1-1 may have a first-1 area in the plan view. The first-1 area may refer to a two-dimensional planar area.

The first charge generation layer CGL1 may be arranged over the first-1 light-emitting unit layer EU1-1, may be arranged in the first-1 light-emitting unit layer EU1-1 in the plan view, and may have a first-2 area that is less than the first-1 area. The first-2 area may also refer to a two-dimensional planar area. For example, the first-2 area may be greater than or equal to 40% (or about 40%) and less than 100% (or about 100%) of the first-1 area.

When the first-2 area is greater than or equal to 40% (or about 40%) and less than 100% (or about 100%) of the first-1 area, the magnitude of a leakage current occurring between the first functional layer 211 and the first charge generation layer CGL1 may be less than 3% (or about 3%) of the magnitude of a vertical current flowing between the first electrode and the second electrode. As the magnitude of the leakage current increases, it may more adversely affect the image quality. The leakage current may be understood as a horizontal current, and when the magnitude of the leakage current is less than 3% (or about 3%) of the magnitude of the vertical current, it may hardly have an adverse effect on the image quality.

As illustrated in FIGS. 11 to 13, the number (e.g., 2) of light-emitting unit layers included in the first light-emitting unit EUb may be greater than the number (e.g., 1) of light-emitting unit layers included in the second light-emitting unit EUg or the number (e.g., 1) of light-emitting unit layers included in the third light-emitting unit EUr.

As illustrated in FIGS. 11 to 13, the end of the first-2 light-emitting unit layer EU1-2 may cover the upper surface of the end of the first-1 light-emitting unit layer EU1-1 in the plan view. The end of the first-2 light-emitting unit layer EU1-2 may directly contact the end of the first-1 light-emitting unit layer EU1-1.

As illustrated in FIGS. 11 to 13, the first-2 light-emitting unit layer EU1-2 may be arranged over the first charge generation layer CGL1 and may overlap the first-1 light-emitting unit layer EU1-1. For example, in the plan view, the first-2 light-emitting unit layer EU1-2 may have a first-3 area that is greater than the first-2 area.

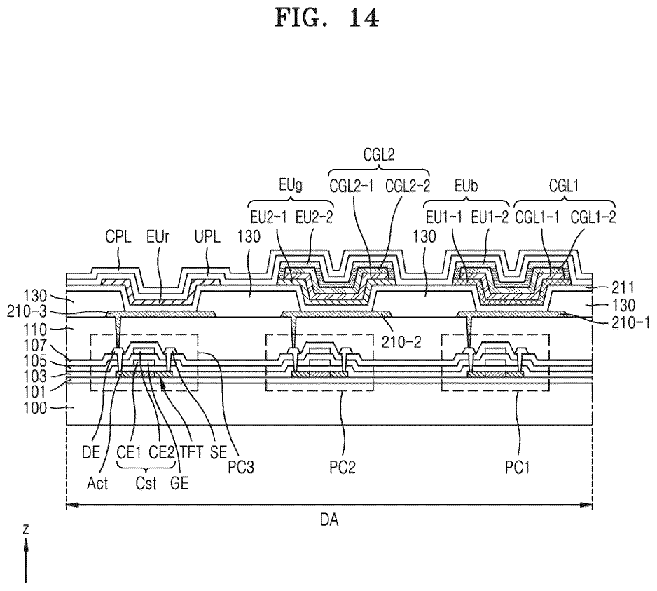

FIG. 14 is a cross-sectional view schematically illustrating an example of the cross-section of the display apparatus 11 of FIG. 1.

As illustrated in FIG. 14, the second light-emitting unit EUg may include a second-1 light-emitting unit layer EU2-1 and a second-2 light-emitting unit layer EU2-2. The second light-emitting unit EUg may further include a second charge generation layer CGL2 arranged between the second-1 light-emitting unit layer EU2-1 and the second-2 light-emitting unit layer EU2-2.

The second charge generation layer CGL2 may be arranged over the second-1 light-emitting unit layer EU2-1. The second charge generation layer CGL2 may have the features of the first charge generation layer CGL1 described above and may be arranged on the same layer as the first charge generation layer CGL1.

For example, the second charge generation layer CGL2 may include a second-1 charge generation layer CGL2-1 and a second-2 charge generation layer CGL2-2, and in the plan view, the second charge generation layer CGL2 may be arranged in the second-1 light-emitting unit layer EU2-1. In the plan view, the edge of the second charge generation layer CGL2 may be arranged on an inner side than the edge of the second-1 light-emitting unit layer EU2-1.

The edge of the second-1 charge generation layer CGL2-1 and the edge of the second-2 charge generation layer CGL2-2 may overlap each other in the plan view. The side surface of the second-1 charge generation layer CGL2-1 and the side surface of the second-2 charge generation layer CGL2-2 may form a continuous surface.

The second-1 charge generation layer CGL2-1 may cover at least a portion of the upper surface of the second-1 light-emitting unit layer EU2-1. For example, the second-1 charge generation layer CGL2-1 may not cover an edge of the upper surface of the second-1 light-emitting unit layer EU2-1.

The second-2 charge generation layer CGL2-2 may cover the upper surface of the second-1 charge generation layer CGL2-1. For example, the second-2 charge generation layer CGL2-2 may not cover the outer surface of the second-1 charge generation layer CGL2-1.

The second-2 light-emitting unit layer EU2-2 may be arranged over the second charge generation layer CGL2. The second-2 light-emitting unit layer EU2-2 may cover the upper surface of the second charge generation layer CGL2. The second-2 light-emitting unit layer EU2-2 may cover the outer surface of the second charge generation layer CGL2. For example, the second-2 light-emitting unit layer EU2-2 may directly contact the second-1 light-emitting unit layer EU2-1.

The upper functional layer UPL may cover the first light-emitting unit EUb and the second light-emitting unit EUg. For example, the upper functional layer UPL may cover the upper surface of the second light-emitting unit EUg and the outer surface of the second light-emitting unit EUg. For example, the upper functional layer UPL may cover the upper surface and the outer surface of the second-2 light-emitting unit layer EU2-2 and the outer surface of the second-1 light-emitting unit layer EU2-1. The capping layer CPL may cover the upper surface of the upper functional layer UPL.

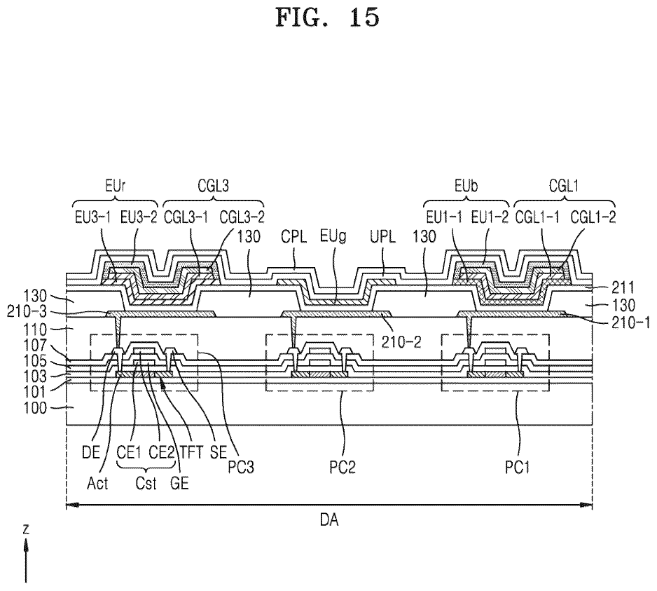

FIG. 15 is a cross-sectional view schematically illustrating an example of the cross-section of the display apparatus 11 of FIG. 1.

As illustrated in FIG. 15, the third light-emitting unit EUr may include a third-1 light-emitting unit layer EU3-1 and a third-2 light-emitting unit layer EU3-2. The third light-emitting unit EUr may further include a third charge generation layer CGL3 arranged between the third-1 light-emitting unit layer EU3-1 and the third-2 light-emitting unit layer EU3-2.

The third charge generation layer CGL3 may be arranged over the third-1 light-emitting unit layer EU3-1. The third charge generation layer CGL3 may have the features of the first charge generation layer CGL1 described above and may be arranged on the same layer as the first charge generation layer CGL1.

For example, the third charge generation layer CGL3 may include a third-1 charge generation layer CGL3-1 and a third-2 charge generation layer CGL3-2, and in the plan view, the third charge generation layer CGL3 may be arranged in the third-1 light-emitting unit layer EU3-1. In the plan view, the edge of the third charge generation layer CGL3 may be arranged on an inner side than the edge of the third-1 light-emitting unit layer EU3-1.

The edge of the third-1 charge generation layer CGL3-1 and the edge of the third-2 charge generation layer CGL3-2 may overlap each other in the plan view. The side surface of the third-1 charge generation layer CGL3-1 and the side surface of the third-2 charge generation layer CGL3-2 may form a continuous surface.

The third-1 charge generation layer CGL3-1 may cover at least a portion of the upper surface of the third-1 light-emitting unit layer EU3-1. For example, the third-1 charge generation layer CGL3-1 may not cover an edge of the upper surface of the third-1 light-emitting unit layer EU3-1.

The third-2 charge generation layer CGL3-2 may cover the upper surface of the third-1 charge generation layer CGL3-1. For example, the third-2 charge generation layer CGL3-2 may not cover the outer surface of the third-1 charge generation layer CGL3-1.

The third-2 light-emitting unit layer EU3-2 may be arranged over the third-1 charge generation layer CGL3. The third-2 light-emitting unit layer EU3-2 may cover the upper surface of the second charge generation layer CGL2. The third-2 light-emitting unit layer EU3-2 may cover the outer surface of the third charge generation layer CGL3. For example, the third-2 light-emitting unit layer EU3-2 may directly contact the third-1 light-emitting unit layer EU3-1.

The upper functional layer UPL may cover the first light-emitting unit EUb and the third light-emitting unit EUr. For example, the upper functional layer UPL may cover the upper surface of the third light-emitting unit EUr and the outer surface of the third light-emitting unit EUr. For example, the upper functional layer UPL may cover the upper surface and the outer surface of the third-2 light-emitting unit layer EU3-2 and the outer surface of the third-1 light-emitting unit layer EU3-1. The capping layer CPL may cover the upper surface of the upper functional layer UPL.

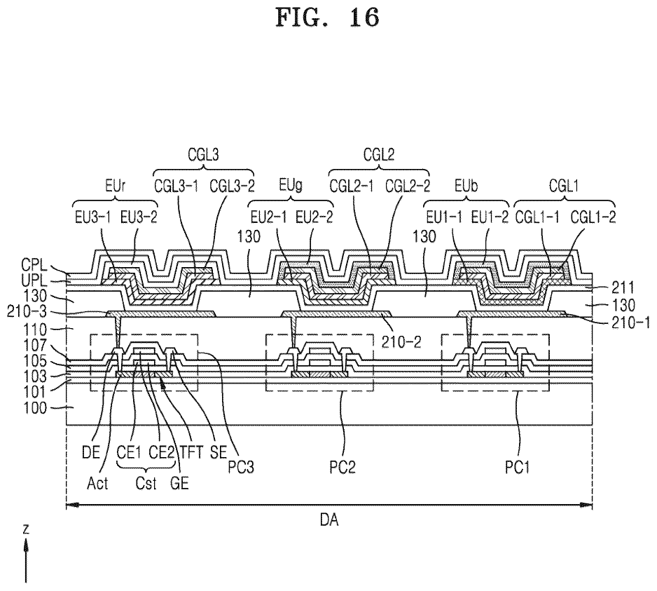

FIG. 16 is a cross-sectional view schematically illustrating an example of the cross-section of the display apparatus 11 of FIG. 1.

As illustrated in FIG. 16, each of the first light-emitting unit EUb, the second light-emitting unit EUg, and the third light-emitting unit EUr may include at least two light-emitting units. Each of the first light-emitting unit EUb, the second light-emitting unit EUg, and the third light-emitting unit EUr may include a functional layer, and the functional layer may be arranged between at least two light-emitting units. A detailed description of each of the first light-emitting unit EUb, the second light-emitting unit EUg, and the third light-emitting unit EUr may be the same as that given above with reference to FIGS. 13 to 15 and thus will be omitted for conciseness.

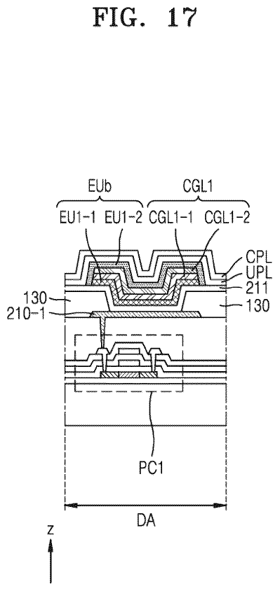

FIGS. 17 to 19 are cross-sectional views focusing on the structural features between the first-1 light-emitting unit layer EU1-1, the first-2 light-emitting unit layer EU1-2, and the first functional layer 211 of the display apparatus 11 of FIG. 1.

For reference, FIGS. 17 to 19 focus on the first light-emitting unit EUb; however, this is merely for convenience of description. The features of the first light-emitting unit EUb of FIGS. 4 to 13 may be equally applied to the second light-emitting unit EUg and the third light-emitting unit EUr illustrated in FIGS. 14 to 16.

As illustrated in FIG. 17, the first-2 light-emitting unit layer EU1-2 not only may cover the upper surface of the first functional layer 211 but also may cover the outer surface of the first functional layer 211. The first-2 light-emitting unit layer EU1-2 may extend to the outer surface of the first-1 light-emitting unit layer EU1-1 and cover the outer surface of the first-1 light-emitting unit layer EU1-1. The end of the first-2 light-emitting unit layer EU1-2 may directly contact the outer surface of the first-1 light-emitting unit layer EU1-1.

The outer surface of the first-1 light-emitting unit layer EU1-1 and the outer surface of the first functional layer 211 may form a continuous surface. However, even when the outer surface of the first-1 light-emitting unit layer EU1-1 and the outer surface of the first functional layer 211 do not form a continuous surface and the first functional layer 211 and the first-1 light-emitting unit layer EU1-1 form a step, the first-2 light-emitting unit layer EU1-2 may cover the outer surface of the first-1 light-emitting unit layer EU1-1. This may be clearly understood by those of ordinary skill in the art from only the illustration in FIG. 17.

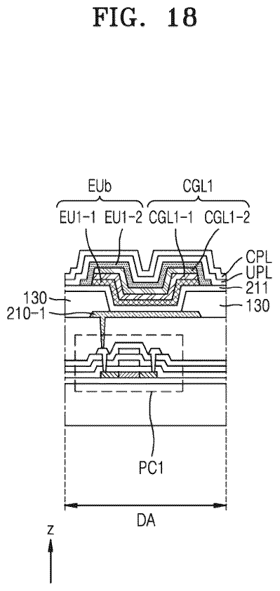

As illustrated in FIG. 18, the first-2 light-emitting unit layer EU1-2 may cover the outer surfaces of the first functional layer 211 and the first-1 light-emitting unit layer EU1-1, and also, the end (or edge) of the first-2 light-emitting unit layer EU1-2 may protrude along the upper surface of the first functional layer 211. The end (or edge) of the first-2 light-emitting unit layer EU1-2 may form a step with respect to the upper surface of the first functional layer 211.

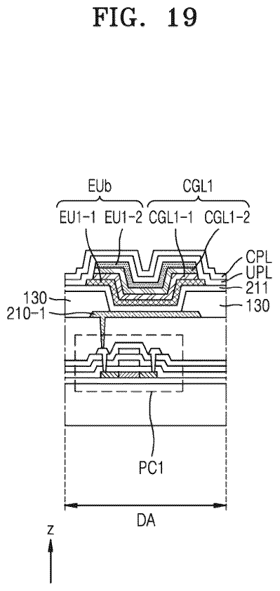

As illustrated in FIG. 19, the first-2 light-emitting unit layer EU1-2 may not cover the outer surface of the first charge generation layer CGL1. The first-1 light-emitting unit layer EU1-1 may surround the first charge generation layer CGL1 in the plan view, and the first charge generation layer CGL1 may be arranged in the first-1 light-emitting unit layer EU1-1 in the plan view. In the cross-sectional view, the end (or edge) of the first-1 light-emitting unit layer EU1-1 may protrude outward from the outer surface of the first charge generation layer CGL1.

Table 1 below summarizes the area and leakage current of the first-2 opening of the first-2 mask.

TABLE 1

| Area of first- | Leakage |
|---|---|
| 2 opening (%) | current (%) |
| 100 | 2.42 |
| 90 | 2.00 |
| 80 | 1.39 |
| 70 | 0.92 |
| 60 | 0.51 |

However, the area of the first-2 opening may be the first-2 area described above and may be represented as the ratio with respect to the area of the first-1 opening. The leakage current may refer to a vertical current occurring between the first functional layer 211 and the first charge generation layer CGL1, and the magnitude of the leakage current may be represented as the ratio with respect to the magnitude of a vertical current flowing between the first electrode (the first pixel electrode) and the second electrode (the opposite electrode).

Referring to Table 1, it may be seen that the leakage current decreases as the area of the first-2 opening decreases compared to the area of the first-1 opening.

For example, when the first-2 area is 60%-90% (or about 60% to about 90%) of the first-1 area, the magnitude of a leakage current occurring between the first functional layer 211 and the first charge generation layer CGL1 may be 2% (or about 2%) or less of the magnitude of a vertical current flowing between the first electrode and the second electrode.

For example, the first-2 area may be 60% to 70% (or about 60% to about 70%) of the first-1 area, and the magnitude of a leakage current occurring between the first functional layer 211 and the first charge generation layer CGL1 may be 1% (or about 1%) or less of the magnitude of a vertical current flowing between the first electrode and the second electrode.

Hereinafter, an electronic apparatus according to some embodiments will be described in detail based on the above descriptions.

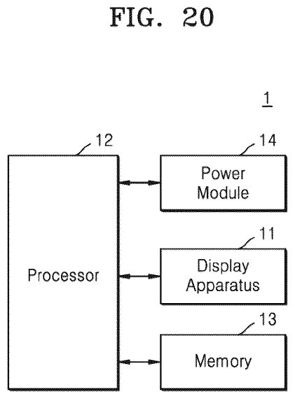

FIG. 20 is a block diagram of an electronic apparatus according to some embodiments.

Referring to FIG. 20, an electronic apparatus 1 according to some embodiments may include a display apparatus 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display apparatus 11. When the processor 12 executes an application stored in the memory 13, an image data signal and/or an input control signal may be transmitted to the display apparatus 11 and the display apparatus 11 may process the received signal and output image information on a display screen.

The power module 14 may include a power supply module such as a power adapter or a battery device, and a power conversion module that converts the power supplied by the power supply module to generate power necessary for the operation of the electronic apparatus 1.

At least one of the components of the electronic apparatus 1 described above may be included in the display apparatus according to embodiments described above. Also, some of the individual modules functionally included in one module may be included in the display apparatus, and some others thereof may be provided separately from the display apparatus. For example, the display apparatus may include the display apparatus 11, and the processor 12, the memory 13, and the power module 14 may be provided in the form of other devices in the electronic apparatus 1 that is not the display apparatus.

The display apparatus 11 of FIG. 20 may be one of the examples of the display apparatus 11 described above with reference to FIGS. 1 to 19. For convenience of description, other descriptions will be omitted; however, those of ordinary skill in the art may easily and clearly understand the display apparatus 11 of FIG. 20 based on the description given above with reference to FIGS. 1 to 19.

According to some embodiments, the electronic apparatus 1 may include a memory 13 that stores data information, a processor 12 that generates a data signal and/or a control signal based on the data information, and a display apparatus 11 that operates based on the data signal and/or the control signal. The display apparatus 11 may be any one of the display apparatuses of FIGS. 1 to 20.

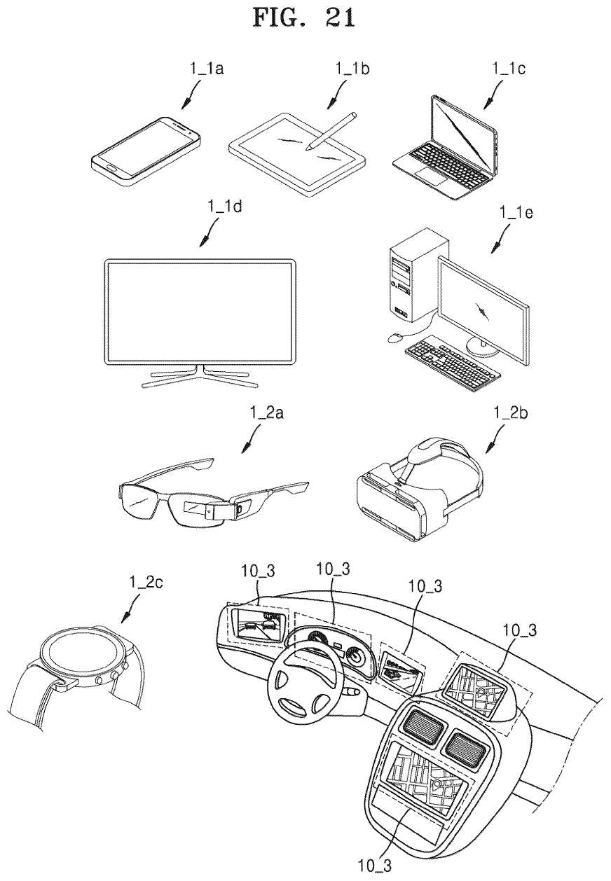

FIG. 21 schematically illustrates electronic apparatuses according to various embodiments.

Referring to FIG. 21, various electronic apparatuses including the display apparatus according to embodiments may include not only an electronic apparatus for displaying images, such as a smart phone 1_1a, a tablet personal computer (PC) 1_1b, a laptop computer 1_1c, a television (TV) 1_1d, or a desk monitor 1_1e, but also a wearable electronic apparatus including a display apparatus, such as smart glasses 1_2a, a head-mounted display 1_2b, or a smart watch 1_2c, and a vehicle electronic apparatus 10_3 including a display apparatus, such as a center information display (CID) or a room mirror display arranged in the instrument panel, center fascia, or dashboard of a car.

As described above, according to some embodiments, a display apparatus with relatively improved image quality, a method of manufacturing the display apparatus, and an electronic apparatus including the display apparatus may be implemented. However, the scope of embodiments according to the present disclosure is not limited to these characteristics.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a first electrode;
a first functional layer over the first electrode and comprising a P dopant;
first to third light-emitting units over the first functional layer; and
a second electrode over the first to third light-emitting units,
wherein the first light-emitting unit comprises:
a first-1 light-emitting unit layer having a first-1 area in a plan view;
a first charge generation layer over the first-1 light-emitting unit layer, in the first-1 light-emitting unit layer in the plan view, and having a first-2 area that is less than the first-1 area; and
a first-2 light-emitting unit layer over the first charge generation layer and overlap the first-1 light-emitting unit layer,
wherein the first-2 area is greater than or equal to 40% and less than 100% of the first-1 area.

2. The display apparatus of claim 1, wherein a magnitude of a leakage current occurring between the first functional layer and the first charge generation layer is less than 3% of a magnitude of a vertical current flowing between the first electrode and the second electrode.

3. The display apparatus of claim 1, wherein a number of light-emitting unit layers included in the first light-emitting unit is greater than a number of light-emitting unit layers included in the second light-emitting unit or a number of light-emitting unit layers included in the third light-emitting unit.

4. The display apparatus of claim 1, wherein the first charge generation layer comprises:
an n-type first-1 charge generation layer over the first-1 light-emitting unit layer; and
a p-type first-2 charge generation layer over the first-1 charge generation layer,
wherein the first-1 charge generation layer is spaced apart from the first functional layer by the first-1 light-emitting unit layer.

5. The display apparatus of claim 1, wherein the first-2 light-emitting unit layer covers an upper surface and an outer surface of the first charge generation layer.

6. The display apparatus of claim 5, wherein, in the plan view, an end of the first-2 light-emitting unit layer covers an upper surface of an end of the first-1 light-emitting unit layer.

7. The display apparatus of claim 6, wherein the end of the first-2 light-emitting unit layer directly contacts the end of the first-1 light-emitting unit layer.

8. The display apparatus of claim 1, wherein, in the plan view, the first-2 light-emitting unit layer has a first-3 area that is greater than the first-2 area.

9. The display apparatus of claim 1, wherein the first-2 area is in a range of 60% to 90% of the first-1 area, and
a magnitude of a leakage current occurring between the first functional layer and the first charge generation layer is 2% or less of a magnitude of a vertical current flowing between the first electrode and the second electrode.

10. The display apparatus of claim 1, wherein the first-2 area is in a range of 60% to 70% of the first-1 area, and
a magnitude of a leakage current occurring between the first functional layer and the first charge generation layer is 1% or less of a magnitude of a vertical current flowing between the first electrode and the second electrode.

11. The display apparatus of claim 1, wherein the first-1 light-emitting unit layer and the first-2 light-emitting unit layer are configured to generate visible light of a first wavelength band.

12. A method of manufacturing a display apparatus, the method comprising:
forming a first functional layer over a first electrode;
forming a first-1 light-emitting unit layer over the first functional layer by using a first-1 mask having a first-1 opening having a first-1 area;
forming a first charge generation layer over the first-1 light-emitting unit layer by using a first-2 mask having a first-2 opening having a first-2 area that is less than the first-1 area;
forming a first-2 light-emitting unit layer over the first charge generation layer by using a first-3 mask having a first-3 opening having a first-3 area; and
forming a second electrode over the first-2 light-emitting unit layer,
wherein the first-2 area is greater than or equal to 40% and less than 100% of the first-1 area.

13. The method of claim 12, wherein a magnitude of a leakage current occurring between the first functional layer and the first charge generation layer is less than 3% of a magnitude of a vertical current flowing between the first electrode and the second electrode.

14. The method of claim 12, wherein the first-3 area is greater than the first-2 area.

15. The method of claim 14, wherein the first-2 light-emitting unit layer covers an upper surface and a side surface of the first charge generation layer.

16. The method of claim 12, wherein the first-2 area is greater than or equal to 60% and less than 90% of the first-1 area, and
a magnitude of a leakage current occurring between the first functional layer and the first charge generation layer is 2% or less of a magnitude of a vertical current flowing between the first electrode and the second electrode.

17. The method of claim 12, wherein the first-2 area is in a range of 60% to 70% of the first-1 area, and
a magnitude of a leakage current occurring between the first functional layer and the first charge generation layer is 1% or less of a magnitude of a vertical current flowing between the first electrode and the second electrode.

18. The method of claim 12, wherein the first-1 light-emitting unit layer and the first-2 light-emitting unit layer are configured to generate visible light of a first wavelength band.

19. An electronic apparatus comprising:
a memory storing data information;
a processor configured to generate a data signal and/or a control signal based on the data information; and
a display apparatus configured to operate based on the data signal and/or the control signal,
wherein the display apparatus comprises:
a first electrode;
a first functional layer over the first electrode;
first to third light-emitting units over the first functional layer; and
a second electrode over the first to third light-emitting units,
wherein the first light-emitting unit comprises:
a first-1 light-emitting unit layer having a first-1 area in a plan view;
a first charge generation layer over the first-1 light-emitting unit layer, in the first-1 light-emitting unit layer in the plan view, and having a first-2 area that is less than the first-1 area; and
a first-2 light-emitting unit layer over the first charge generation layer and overlapping the first-1 light-emitting unit layer,
wherein the first-2 area is greater than or equal to 40% and less than 100% of the first-1 area.

20. The electronic apparatus of claim 19, wherein a magnitude of a leakage current occurring between the first functional layer and the first charge generation layer is less than 3% of a magnitude of a vertical current flowing between the first electrode and the second electrode.
